(19) United States
(12) Patent Application Publication
(10) Pub. No.: US 2002/0167336 A1
(43) Pub. Date: Nov. 14, 2002

(54) Microprocessor circuit for allowing input and output via a single pin

(76) Inventors: J. Scott Jamieson, Waukesha, WI (US); Lawrence A. Armstrong, New Berlin, WI (US)

Correspondence Address: QUARLES & BRADY LLP, 411 E. WISCONSIN AVENUE, SUITE 2040, MILWAUKEE, WI, 53202-4497, US

(21) Appl. No.: 09/851,916

(22) Filed: May 9, 2001

(51) Int. Cl. H03K 19/00

(52) U.S. Cl. 326/99

(57) ABSTRACT

A microprocessor circuit, and a method of monitoring and controlling an outside device using a single pin of a microprocessor, are disclosed. The microprocessor circuit includes a microprocessor having a pin, a first junction and a second junction that are both electrically coupled to the pin, and a capacitor by which the second junction is electrically coupled to the pin. The microprocessor circuit is capable of receiving at the first junction an input signal and providing a related signal to the pin in response to the input signal. The capacitor prevents signals below a certain frequency level from being communicated from the pin to the second junction. The microprocessor is capable of generating a control signal at the pin that includes at least one component that is above the certain frequency level, so that the generating of the control signal produces an output signal at the second junction.

### FIELD OF THE INVENTION

The present invention relates generally to microprocessor circuits and other control circuits, and more particularly to microprocessor circuits that both receive inputs and provide outputs to control complex systems.

### BACKGROUND OF THE INVENTION

Control circuits such as microprocessor circuits and other microcontrollers are utilized in a variety of conventional systems to allow for control and monitoring of the operation of such systems. Often, the microprocessor circuits include, in addition to a discrete microprocessor device, additional external circuit devices that are coupled to the microprocessor and allow it to function in particular desired manners. Frequently, the microprocessor circuits are able to receive and process input signals, and also are able to output control signals or other informational signals.

The exact operation and design of a particular microprocessor circuit will depend to some extent upon the type of system that the microprocessor circuit is being designed to control or monitor. Specifically in the case of heating, ventilation and air-conditioning systems, many of these systems require the use of a microprocessor circuit that can both receive input signals from devices such as a thermostat, and also provide output signals to devices that require control such as relays. Further, certain of the systems are capable of receiving output signals from the microprocessor circuit that are in a pulse format to allow for the control of SCR or triac-based relay drivers.

Although microprocessor circuits can be effectively implemented in a wide variety of systems, the use of such circuits is constrained by the number of input and output (I/O) pins that are available for signal transmission into and out of the discrete microprocessor device. For example, in many HVAC systems, to be cost effective, small microprocessors with a limited pin count must be used. Additionally, for cost and safety reasons, a traditional I/O multiplexer may not be used. Because the number of microprocessor I/O pins is limited, the number of I/O signals that can be communicated to and from the microprocessor is also limited.

It therefore would be advantageous if a microprocessor circuit could be developed that allowed I/O signals to be communicated to and from the microprocessor in a more efficient manner so that an increased amount of information and control signals could be communicated to and from the microprocessor given the existing number of I/O pins. It would further be advantageous if the new microprocessor circuit did not require a significant number of new circuit elements or other changes relative to conventional microprocessor circuits, such that the manufacturing of the new microprocessor circuit did not require a significant amount of added expense or difficulty relative to conventional microprocessor circuits.

### SUMMARY OF THE INVENTION

The present inventors have discovered that a microprocessor circuit can be developed in which a single I/O pin of the microprocessor can both receive input signals from, and communicate output control signals to, a given system being controlled and monitored by the microprocessor circuit. The input signals, which are alternating current (AC) and oscillate at a relatively low frequency, are provided to the I/O pin of the microprocessor through a current-limiting resistor. Internal to the microprocessor, the I/O pin is coupled by diodes between both ground and a supply voltage, such that the input signal observed by the microprocessor (at the pin) is effectively a trapezoidal wave with upper and lower bounds formed due to the operation of the diodes. Additionally, the single I/O pin is coupled, by way of a relatively high-impedance (at low frequencies, e.g., 60 Hz) capacitor outside of the microprocessor, to a pulse-activated relay device such as a SCR-based relay driver.

By way of transistor switches within the microprocessor that are capable of coupling the single pin between ground and the supply voltage, the microprocessor is able to force the voltage of the single pin to deviate from that provided by the input signal. By appropriately controlling the internal transistors, the microprocessor is able to rapidly switch the voltage of the single pin such that pulses are transmitted through the high-impedance capacitor to control the pulse-activated relay device. Because the switching action of the internal transistors creates signals having frequency components that are high relative to the input signal, the microprocessor is able to both receive the input signal and provide the control signals by way of the same single I/O pin, without the input signal affecting the SCR-based relay driver.

In particular, the present invention relates to a microprocessor circuit. The microprocessor circuit includes a microprocessor having a pin, a first junction and a second junction that are both electrically coupled to the pin, and a capacitor by which the second junction is electrically coupled to the pin. The microprocessor circuit is capable of receiving at the first junction an input signal and providing a related signal to the pin in response to the input signal. The capacitor prevents signals below a certain frequency level from being communicated from the pin to the second junction. The microprocessor is capable of generating a control signal at the pin that includes at least one component that is above the certain frequency level, so that the generating of the control signal produces an output signal at the second junction.

The present invention further relates to a microprocessor circuit. The microprocessor circuit includes a microprocessor having a pin, and an input junction electrically coupled to the pin so that, when an input signal is received at the input junction, a related signal is provided to the pin. The microprocessor circuit additionally includes an output junction, and a buffering means coupled between the pin and the output junction for preventing a class of signals from being communicated from the pin to the output junction. The buffering means is configured so that the related signal provided to the pin in response to the input signal is within the class of signals that are prevented from being communicated to the output junction. The buffering means is further configured so that a control signal generated by the microprocessor at the pin includes at least one component that is not within the class of signals that are prevented from being communicated to the output junction.

The present invention additionally relates to a method of monitoring and controlling an outside device using a single pin of a microprocessor. The method includes providing the microprocessor with the single pin, an input junction coupled to the single pin, and an output junction coupled to the single pin by way of a buffering device. The method further includes receiving at the input junction an input signal that originated from the outside device and providing, based upon the input signal, a related signal to the single pin. The method additionally includes sampling the related signal at the single pin at a first time, and generating a control signal at the single pin at a second time. The method further includes communicating at least one component of the control signal by way of the buffering device to produce an output signal capable of influencing an operation of the outside device.

### BRIEF DESCRIPTION OF THE DRAWINGS

FIG. 1 is a schematic diagram showing an exemplary embodiment of a microprocessor circuit capable of operating to receive input signals and provide output signals with respect to an exemplary controlled device, where the microprocessor of the microprocessor circuit is capable of receiving the input signals and providing the output signals by way of a single pin;

FIG. 2 is a graph showing an exemplary sinusoidal input signal that is provided by the exemplary controlled device to the microprocessor circuit of FIG. 1;

FIG. 3 is a graph showing an exemplary time-variation of the voltage at the single pin of the microprocessor of the microprocessor circuit of FIG. 1;

FIG. 4 is a graph showing a second exemplary time-variation of the voltage at the single pin of the microprocessor of the microprocessor circuit of FIG. 1, in which the voltage is varied so that the output signals provided to the exemplary controlled device include a triggering voltage spike;

FIG. 5 is a graph showing the output signals provided to the exemplary controlled device given the time-variation of the voltage at the single pin shown in FIG. 4;

FIG. 6 is a graph showing a third exemplary time variation of the voltage at the single pin of the microprocessor of the microprocessor circuit of FIG. 1 in the case where the input signal is zero (e.g., the input signal is not present), and in which the voltage of the single pin is varied so that the output signals provided to the exemplary controlled device include a triggering voltage spike; and

FIG. 7 is a is a graph showing the output signals provided to the exemplary controlled device given the time-variation of the voltage at the single pin shown in FIG. 6.

### DETAILED DESCRIPTION OF THE INVENTION

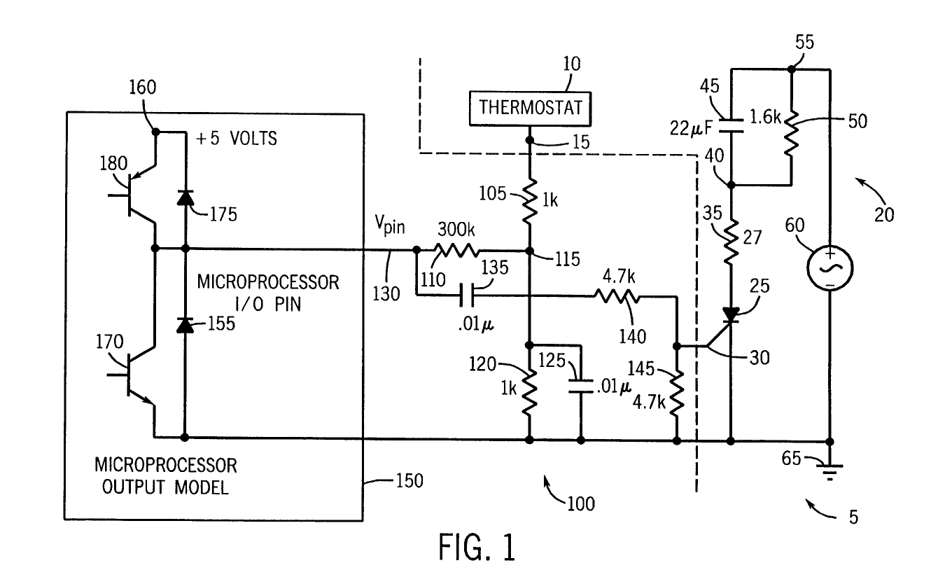

Referring to FIG. 1, an exemplary microprocessor circuit 100 monitors and controls an exemplary controlled device 5. In the embodiment of FIG. 1, the exemplary controlled device 5 includes both a thermostat 10, which is monitored, and a controllable relay circuit 20. The thermostat 10 provides an input voltage signal 15 that is input to the exemplary microprocessor circuit 100. The input voltage 15 is sinusoidal, although in alternate embodiments it can also be zero or another type of signal (e.g., a DC signal). In alternate embodiments, the exemplary controlled device 5 can vary from that of FIG. 1. Depending upon the embodiment, the exemplary controlled device 5 can be made up of a single controlled device or multiple devices.

The controllable relay circuit 20 includes, in the embodiment shown, an SCR-based relay driver including a silicon-controlled rectifier (SCR) 25, such as the MCR22-6 SCR manufactured by Motorola, Inc. of Schaumburg, Ill. The SCR 25 is coupled between a ground terminal 65 and a first resistor 35, and conducts current after receiving a positive voltage pulse or spike at an input terminal 30 until such time as the current flowing through the SCR 25 becomes zero. In alternate embodiments, other types of relay drivers can be employed, such as triac-based relay drivers. The exemplary controllable relay circuit 20 further includes a sinusoidal voltage source 60 coupled between the ground terminal 65 and a voltage supply node 55. Additionally, a first capacitor 45 and a relay 50 are connected in parallel with one another between the voltage supply node 55 and an intermediate node 40. The first resistor 35 is coupled between the intermediate node 40 and the SCR 25. Exemplary values for the first resistor 35, the relay 50, and the first capacitor 45 are shown to be 27 Ω, 1.6 KΩ, and 22 μF, respectively.

With respect to the exemplary microprocessor circuit 100 as shown in FIG. 1, this circuit includes a microprocessor 150 that has at least one input/output (I/O) pin and typically will have multiple such I/O pins. In particular, FIG. 1 shows a single I/O pin 130, which in accordance with the present invention is capable of being utilized by the microprocessor 150 both to receive input signals and to provide output signals.

Coupled to the single I/O pin 130 are several circuit elements that are employed to provide an input voltage signal at I/O pin 130 that is related to the input voltage signal 15. In the embodiment shown, these circuit elements include a first resistor 105, a second resistor 110, a third resistor 120 and a first capacitor 125, for which exemplary values are shown to be 1 KΩ, 300 KΩ, 1 KΩ and 0.01 μF, respectively. Specifically, the input voltage signal 15 is provided to a first terminal of the first resistor 105, the second terminal of which is coupled to an intermediate node 115. The third resistor 120 and first capacitor 125 are coupled in parallel between the intermediate node 115 and the ground terminal 65, while the second resistor 110 is coupled between the intermediate node 115 and the single I/O pin 130.

In the embodiment shown, the resistance values of the first and third resistors 105,120 are set to be equal to one another so that the voltage at the intermediate node 115 between the two resistors at any given time is approximately equal to one-half of the magnitude of the input voltage signal 15 at that time. Also, the relatively high value of the second resistor 110 is set so that the microprocessor 150 receives very low input currents at the I/O pin 130. The first capacitor 125 acts to filter noise to ground. The exact values of the resistors 105,110,120 and the first capacitor 125 can vary from those shown depending upon the embodiment. Due to the operation of the resistors 105,110,120 and capacitor 125, the input voltage signal that would be received by the I/O pin 130 in the absence of other circuitry (discussed below) would be approximately sinusoidal with the same frequency as the frequency of the input voltage signal 15 (without noise).

Additionally, the microprocessor circuit 100 includes a second capacitor 135 coupled between the single pin 130 and a fourth resistor 140, which in turn is coupled to a fifth resistor 145, which in turn is coupled to the ground terminal 65. The input terminal 30 to the SCR 25 is shown to be coupled to a node intermediate the fourth and fifth resistors 140,145. In the embodiment shown, the values of the fourth and fifth resistors 140,145 are both shown to be equal to 4.7 KΩ. The value of the fourth resistor 140 is chosen to limit current to a suitable level and the value of the fifth resistor 145 is chosen to enhance the thermal stability of the SCR 25.

With respect to the microprocessor 150 itself, in the present embodiment of FIG. 1, the microprocessor is shown to include special circuitry including a first diode 155, a second diode 175, a first internal transistor 170 and a second internal transistor 180. As shown, the first diode 155 is coupled between the single I/O pin 130 and the ground terminal 65, and allows current flow in the direction from the ground terminal toward the single I/O pin. The second diode 175 is coupled between the single I/O pin 130 and a positive supply voltage terminal 160, which in the embodiment shown is +5 volts DC.

Additionally, the first and second internal transistors 170,180 can be any of a variety of different types of active devices including, for example, CMOS (Complementary Metal Oxide Semiconductor) devices or bipolar junction transistors. In the embodiment shown in FIG. 1 (which is merely representative of one possible embodiment of the microprocessor 150 among many possible embodiments), the first internal transistor 170 is a NPN transistor having its emitter terminal coupled to the ground terminal 65, and its collector terminal coupled to the single I/O pin 130. The second internal transistor 180 is a PNP transistor having its emitter terminal coupled to the positive supply voltage terminal 160, and its collector terminal coupled to the single I/O pin 130. The base terminals of each of the first and second internal transistors 170, 180 are controlled by additional control circuitry of the microprocessor (not shown), which determines when and whether the transistors are turned on and off.

Because of the special circuitry internal to the microprocessor 150, the input voltage signal received by the microprocessor at the single I/O pin 130 is no longer sinusoidal even though the input voltage signal 15 is sinusoidal. Rather, although the input voltage signal received by the microprocessor at the single I/O pin 130 is related to the input voltage signal 15, the input voltage signal at the single I/O pin (the “related signal”) is effectively a digital input signal that switches on and off rather than a sinusoidal signal. When, due to the variation in the input voltage signal 15, the related signal attempts to attain a voltage level of greater than 5.6 volts, which equals the voltage of the supply voltage terminal plus a 0.6 volt voltage drop across the second diode 175 itself, the second diode conducts current and precludes the voltage on the single I/O pin 130 from exceeding 5.6 volts.

Likewise, when the related signal attempts to fall below a voltage of −0.6 volts, the first diode 155 conducts current and precludes the voltage on the single I/O pin 130 from falling below −0.6 volts. Thus, the first and second diodes 155,175 operate to protect the microprocessor 150 from experiencing excessive voltage levels at the single I/O pin 130, by clamping the voltage at the I/O pin at these high or low voltages when the related signal attempts to cause the voltage at the I/O pin to exceed or fall below these voltages, respectively. In alternate embodiments of the microprocessor 150 in which the microprocessor is capable of handling significantly higher or lower voltages at the single I/O pin 130, the first and second diodes 155,175 are not required.

Additionally, the microprocessor 150 by controlling the transistors 170, 180 can also cause the related signal to vary from the levels it otherwise would attain as a result of the variation of the input voltage signal 15 and the diodes 155,175. Specifically, by switching on the first internal transistor 170 while the second internal transistor 180 is switched off, the microprocessor 150 can force the voltage of the single I/O pin 130 to become approximately equal to zero. Also, by switching on the second internal transistor 180 while the first internal transistor 170 is switched off, the microprocessor 150 can force the voltage of the single I/O pin 130 to attain a high voltage level (e.g., approximately 5 volts).

Although the microprocessor 150 is shown to include the transistors 170, 180 and the diodes 155, 175, these devices are exemplary and will vary depending upon the embodiment. Additionally, the devices need not be discrete circuit devices, but instead in certain embodiments can be implemented as part of the single microprocessor device itself.

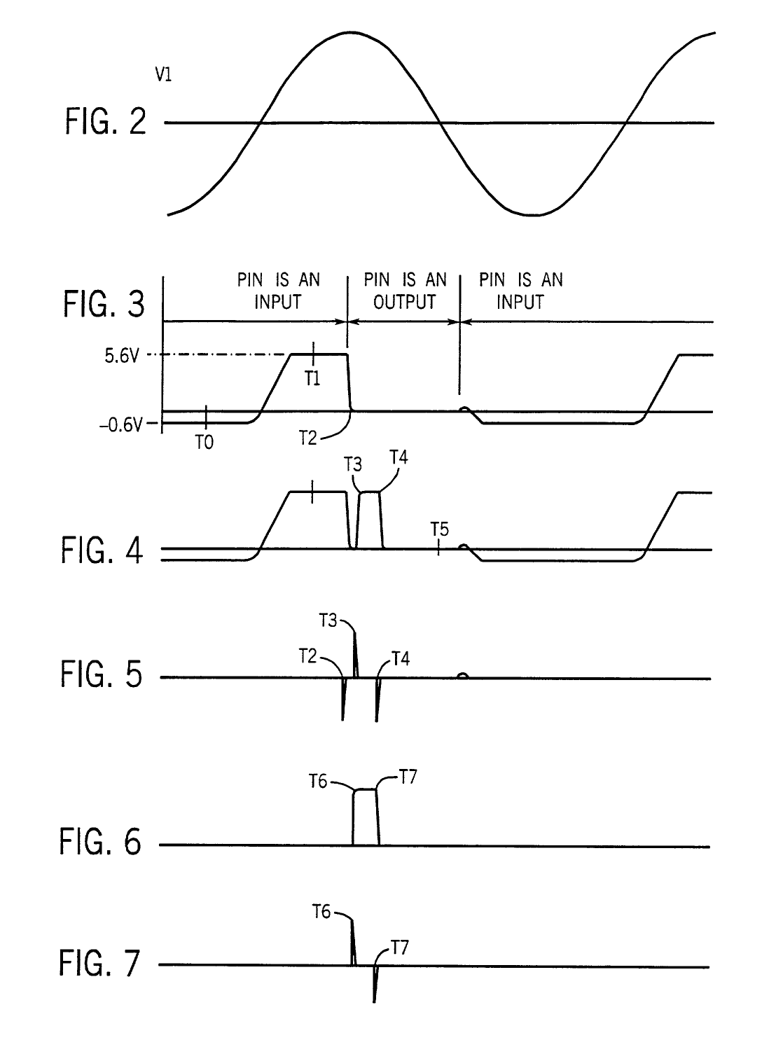

Turning to FIGS. 2-5, graphs are provided showing exemplary operation of the microprocessor circuit 100. Referring to FIG. 2, the input voltage signal 15 provided by the thermostat 10 is in the present embodiment a sinusoidal signal. Because of the diodes 155,175, the related signal that occurs at the single I/O pin 130 in response to the input voltage signal 15 is limited within a discrete range, as shown in FIG. 3. In particular, as shown at time T1, at times where the input voltage signal 15 would tend to drive the voltage at the single I/O pin 130 above 5.6 volts, the operation of the second diode 175 keeps the voltage at the single I/O pin 130 from exceeding 5.6 volts. Likewise, as shown at time T0, at times where the input voltage signal 15 would tend to drive the voltage at the single I/O pin 130 below −0.6 volts, the operation of the first diode 155 keeps the voltage at the single I/O pin at −0.6 volts.

Further with respect to FIG. 3, in accordance with the present embodiment, the microprocessor 150 is configured to operate so that the single I/O pin 130 is treated as an input at certain times and as an output during other times, so that the I/O pin can act both as an input and an output. In particular, at time T1 the microprocessor 150 is configured to receive a sample of the value of the related signal at the I/O pin 130. In order to read the related signal at time T1, the microprocessor 150 is configured to treat the I/O pin 130 as an input early in the positive half cycle of the input voltage signal 15.

The microprocessor circuit 100 also can operate to provide output control signals via the I/O pin 130 as shown in FIG. 3. In the present embodiment, where the SCR 25 is capable of being switched on by applying a positive voltage pulse or spike at the input terminal 30, the microprocessor 100 particularly has a specific time window in which it can provide a useful output control signal. For cases where a capacitor-filter (e.g., the first capacitor 45) is in the relay circuit 20 as shown, the SCR 25 should be triggered near the peak of the sinusoidal input voltage signal 15. As shown in FIG. 3 at time T2, for example, by switching on the first internal transistor 170 (and maintaining the second internal transistor 180 switched off), the microprocessor 150 can force the voltage at the single I/O pin 130 to change from being at approximately 5 volts to approximately zero volts.

As discussed, the SCR 25 of the present embodiment is only switched to an on (conducting) state if it receives a positive voltage pulse or spike at the input terminal 30, and only remains on until the current being conducted becomes zero. Given this manner of operation of the SCR 25, the microprocessor 150 in particular can provide a triggering signal to cause the SCR to turn on by causing the voltage at the single I/O pin 130 to vary as shown in FIG. 4. As shown, at time T2 the microprocessor 150 switches on the first internal transistor 170 to cause the voltage of the single I/O pin 130 to switch to approximately zero volts, to discharge any voltage on the second capacitor 135 due to the effects of the input voltage signal 15.

Then, at time T3, the microprocessor 150 switches off the first internal transistor 170 and switches on the second internal transistor 180 to cause the voltage of the single I/O pin 130 to switch to approximately 5 volts. The time delay between times T3 and T2 should be long enough guarantee that any voltage on the second capacitor 135 due to the effects of the input voltage signal 15 has been discharged. Then, at time T4, the microprocessor 150 switches off the second internal transistor 180 and switches on the first internal transistor 170, to cause the voltage of the single I/O pin 130 to return to about zero volts.

Given this switching action of the first and second internal transistors 170,180, the microprocessor circuit 100 produces three voltage spikes at the input terminal 30 of the SCR 25 as shown in FIG. 5. The first and third voltage spikes, which occur at times T2 and T4, respectively, are negative voltage spikes that have no effect upon the SCR 25. However, the second voltage spike, which is at time T3, is a positive pulse that triggers the SCR 25 to switch on and thereby conduct current.

Once the SCR 25 is turned on at time T3, the SCR 25 conducts current until such time as the amount of current being conducted falls to zero. In the present embodiment, the voltage produced by the sinusoidal voltage source 60 at the voltage supply node 55 is in phase with the input voltage signal 15. Consequently, once the SCR 25 is turned on at time T3, the SCR stays on (conducts) for sufficient time to charge the first capacitor 45, which powers the relay 50 and holds it on through the negative half cycle of the sinusoidal voltage source 60. The process is then repeated on the next positive half cycle. If the first capacitor 45 was not included in the relay circuit 20, the SCR 25 could conduct up until time T5. The first resistor 35 is used to limit the inrush current charging the first capacitor

Because the single I/O pin 130 is coupled to both the input voltage signal 15, and to the input terminal 30 of the SCR 25, the second capacitor 135 is used to buffer the input terminal 30 from receiving the input voltage signal 15. The frequency of the input voltage signal 15 is typically significantly less than the frequency components (or at least some of the frequency components) of the pulses generated by the switching action of the first and second internal transistors 170,180. Consequently, the capacitance value of the second capacitor 135 can be chosen such that the first, second and third pulses produced by the switching action of the first and second internal transistors 170,180 produce the first, second and third voltage spikes at the input terminal 30, while the sinusoidal variation of the input voltage signal 15 is not communicated to the input terminal (nor is the related signal at the single I/O pin 130 loaded appreciably by the resistors 140,145 or the SCR 25).

That is, the capacitance value of the second capacitor 135 is chosen to pass only signal components having frequencies that are significantly higher than the frequency of the input voltage signal 15, such that only the pulses resulting from the switching action of the first and second internal transistors 170,180 can be communicated to and affect the SCR 25. Thus, the single I/O pin 130 is used both to receive the related signal based upon the input voltage signal 15, and to communicate output signals to SCR 25.

Turning to FIGS. 6 and 7, the voltages occurring at the single I/O pin 130 and at the input terminal 30 of the SCR 25 are respectively shown in a case where the microprocessor circuit 100 is providing output control signals even though the input voltage signal 15 is zero. As shown in FIG. 6, the voltage at the single I/O pin 130, in the case where the input voltage signal 15 is zero, remains zero up until time T6, at which time it is desired to cause the SCR 25 to turn on. At time T6, the second internal transistor 180 is switched on (while the first internal transistor 170 is switched off), causing the voltage at the single I/O pin 130 to increase to about 5 volts. This produces a positive voltage spike at time T6 at the input terminal 30 of the SCR 25, causing the SCR to turn on. At time T7, the first internal transistor 170 is switched on and the second internal transistor 180 is switched off. Consequently, the voltage of the single I/O pin 130 returns to about zero as shown in FIG. 6, and a negative voltage spike is produced at the input terminal of the SCR as shown in FIG. 7.

In the preferred embodiment, the present invention employs components having carefully-selected values to assure independence of the output function from the input function, even under fault conditions. For example, the fourth and fifth resistors 140,145 should have resistances that are low enough to allow a 5-volt pulse to turn on the SCR 25 and yield good thermal stability of the SCR. At the same time, the resistance of the second resistor 110 should be chosen so that a short of the second capacitor 135 will not allow the input voltage signal 15 to directly turn on the SCR. Further, the second capacitor 135 should have a small enough capacitance value so that it will not load down the input voltage signal 15 as it is supplied through the second resistor 110, but a large enough value to pass the output pulse to the SCR 25.

While the foregoing specification illustrates and describes the preferred embodiments of this invention, it is to be understood that the invention is not limited to the precise construction herein disclosed. The invention can be embodied in other specific forms without departing from the spirit or essential attributes. Accordingly, reference should be made to the following claims, rather than to the foregoing specification, as indicating the scope of the invention.

What is claimed is:

1. A microprocessor circuit comprising:
a microprocessor including a pin;
a first junction and a second junction that are both electrically coupled to the pin; and
a capacitor by which the second junction is electrically coupled to the pin,
wherein the microprocessor circuit is capable of receiving at the first junction an input signal and providing a related signal to the pin in response to the input signal,
wherein the capacitor prevents signals below a certain frequency level from being communicated from the pin to the second junction, and
wherein the microprocessor is capable of generating a control signal at the pin that includes at least one component that is above the certain frequency level, so that the generating of the control signal produces an output signal at the second junction.

2. The microprocessor circuit of claim 1, wherein the microprocessor includes:
a limiting device capable of preventing a voltage at the pin from exceeding a maximum level and from falling below a minimum level; and
a switching device for allowing the microprocessor to control the voltage at the pin.

3. The microprocessor circuit of claim 2,
wherein the limiting device includes a first diode coupled between the pin and a ground and a second diode coupled between the pin and a voltage supply,
wherein the first diode is coupled so that the first diode conducts current from the ground toward the pin when the voltage at the pin is tending to fall below the minimum level, and
wherein the second diode is coupled so that the second diode conducts current from the pin toward the voltage supply when the voltage at the pin is tending to exceed the maximum level.

4. The microprocessor circuit of claim 3,
wherein the switching device includes a first internal transistor coupled between the pin and the ground and a second internal transistor coupled between the pin and the voltage supply,
wherein the microprocessor can switch on the second internal transistor while the first internal transistor is switched off and cause the voltage at the pin to become approximately equal to that of the voltage supply, and
wherein the microprocessor can switch on the first internal transistor while the second internal transistor is switched off and cause the voltage at the pin to become approximately equal to that of the ground.

5. The microprocessor circuit of claim 2, wherein the input signal is a sinusoidal signal having a frequency below the certain frequency level.

6. The microprocessor circuit of claim 5,
wherein the limiting device acts to prevent the voltage of the pin from exceeding the maximum level even though the input signal is tending to cause the voltage to exceed the maximum level, and acts to prevent the voltage of the pin from falling below the minimum level even though the input signal is tending to cause the voltage to fall below the minimum level.

7. The microprocessor circuit of claim 6, wherein the microprocessor samples the voltage as an indication of the input signal at a first time when the voltage of the pin is limited at the maximum level.

8. The microprocessor circuit of claim 7, wherein the switching device operates to cause the voltage of the pin to be switched from the maximum level to approximately the minimum level at a second time after the first time.

9. The microprocessor circuit of claim 8, wherein the switching device operates to cause the voltage of the pin to be switched from approximately the minimum level to approximately the maximum level at a third time after the second time.

10. The microprocessor circuit of claim 9, wherein the switching device operates to cause the voltage of the pin to be switched from approximately the maximum level to approximately the minimum level at a fourth time after the third time.

11. The microprocessor circuit of claim 9, wherein the switching of the voltage of the pin generates the control signal and results in a negative voltage spike at the second junction at the second time and a positive voltage spike at the second junction at the third time, wherein the negative and positive voltage spikes are included within the output signal.

12. The microprocessor circuit of claim 1, wherein the microprocessor circuit is configured to receive the input signal at the first junction from a thermostat, and is configured to provide the output signal at the second junction to an SCR-based relay driver.

13. The microprocessor circuit of claim 1, further comprising a first resistor and a second resistor coupled in series between the pin and the first junction, and a third resistor and an additional capacitor coupled in parallel with one another between a ground and an intermediate node existing between the first and second resistors.

14. The microprocessor circuit of claim 1, further comprising a first resistor and a second resistor, wherein the first capacitor is coupled between the pin and an intermediate node, wherein the first resistor is coupled between the intermediate node and the second junction, and wherein the second resistor is coupled between the second junction and a ground.

15. The microprocessor circuit of claim 1, wherein the input signal is at least one of zero and a DC signal.

16. A microprocessor circuit comprising:
a microprocessor including a pin;
an input junction electrically coupled to the pin so that, when an input signal is received at the input junction, a related signal is provided to the pin;
an output junction;
a buffering means coupled between the pin and the output junction for preventing a class of signals from being communicated from the pin to the output junction,
wherein the buffering means is configured so that the related signal provided to the pin in response to the input signal is within the class of signals that are prevented from being communicated to the output junction, and
wherein the buffering means is further configured so that a control signal generated by the microprocessor at the pin includes at least one component that is not within the class of signals that are prevented from being communicated to the output junction.

17. The microprocessor circuit of claim 16, further comprising:
a limiting means within the microprocessor for preventing a voltage at the pin from exceeding a first level and from falling below a second level; and
a switching means within the microprocessor for allowing the microprocessor to control the voltage at the pin.

18. A method of monitoring and controlling an outside device using a single pin of a microprocessor, the method comprising:
providing the microprocessor with the single pin, an input junction coupled to the single pin, and an output junction coupled to the single pin by way of a buffering device;
receiving at the input junction an input signal that originated from the outside device;
providing, based upon the input signal, a related signal to the single pin;
sampling the related signal at the single pin at a first time;
generating a control signal at the single pin at a second time; and
communicating at least one component of the control signal by way of the buffering device to produce an output signal capable of influencing an operation of the outside device.

19. The method of claim 18, wherein the buffering device is a capacitor, and the input junction is coupled to the single pin by way of a high-resistance resistor, so that very little current is produced at the single pin in response to the input signal.

20. The method of claim 19, wherein the generating of the control signal includes a switching of a voltage of the single pin to a low level at a third time and a switching of the voltage of the single pin to a high level at the second time, wherein the switching of the voltage at the third time allows the capacitor to discharge a charge buildup, and the switching of the voltage at the third and second times respectively results in the production of the output signal including at least a negative voltage spike at the third time and a positive voltage spike at the second time.
